(19) United States
(12) Patent Application Publication
(10) Pub. No.: US 2012/0025051 A1
(43) Pub. Date: Feb. 2, 2012

(54) DOCKING STATION AND POSITIONING APPARATUS

(75) Inventors: Shigeki Nishiyama, Hino-shi (JP); Tomofumi Miyamoto, Nishitama-gun (JP)

(73) Assignee: KABUSHIKI KAISHA TOSHIBA, Tokyo (JP)

(21) Appl. No.: 13/115,907

(22) Filed: May 25, 2011

(30) Foreign Application Priority Data
Jul. 29, 2010 (JP) 2010-170411

(51) Int. Cl. H05K 7/00; F16M 13/00

(52) U.S. Cl. 248/346.03

(57) ABSTRACT

A docking station includes a main body, a pin, an operation element, a locking mechanism, and a lock releasing mechanism. An electronic device is mounted on the main body. The pin is supported on the main body in a protrudable-retractable manner. The operation element is supported on the main body in a protrudable-retractable manner. The locking mechanism locks the pin in a protruding position. The lock releasing mechanism unlocks the pin locked by the locking mechanism in response to the pressing of the operation element in a direction in which the operation element is retracted by the electronic device. A tip of the pin in the protruding position is located at a higher level than a tip of the operation element in a protruding position. The operation element is located adjacent to the pin.

### CROSS-REFERENCE TO RELATED APPLICATIONS

This application is based upon and claims the benefit of priority from Japanese Patent Application No. 2010-170411, filed Jul. 29, 2010, the entire contents of which are incorporated herein by reference.

### FIELD

Embodiments described herein relate generally to a docking station and a positioning apparatus.

### BACKGROUND

Docking stations to be used in electronic devices are known that comprise a positioning mechanism with protrudable-retractable pins.

Regarding such docking stations, there is a demand for preventing the occurrence of malfunction such as those in which the protrudable-retractable pins get unlocked by mistake.

### BRIEF DESCRIPTION OF THE SEVERAL VIEWS OF THE DRAWINGS

FIG. 1 is an exemplary perspective view of a docking station according to a first embodiment;

FIG. 2 is an exemplary perspective view of a state where an electronic device is mounted on the docking station in the first embodiment;

FIG. 3 is an exemplary vertical cross-sectional view for schematically illustrating a positioning mechanism included in the docking station and an electronic device which is yet to be mounted on the docking station in the first embodiment;

FIG. 4 is an exemplary vertical cross-sectional view for schematically illustrating the positioning mechanism included in the docking station and the electronic device mounted on the docking station in the first embodiment;

FIG. 5 is an exemplary exploded perspective view for schematically illustrating a positioning mechanism included in a docking station according to a second embodiment;

FIG. 6A is an exemplary side view for schematically illustrating the positioning mechanism included in the docking station in a state where pins and operation elements are at protruding positions in the second embodiment;

FIG. 6B is an exemplary side view for schematically illustrating the positioning mechanism included in the docking station in a state where the pins and the operation elements are at retracted positions in the second embodiment;

FIG. 7A is an exemplary plan view for schematically illustrating a portion in the positioning mechanism included in the docking station where an interlocking member and an eject lever are connected, with the eject lever yet to be operated in the second embodiment;

FIG. 7B is an exemplary plan view for schematically illustrating the portion in the positioning mechanism included in the docking station where the interlocking member and the eject lever are connected, with the eject lever already operated in the second embodiment;

FIG. 8 is an exemplary vertical cross-sectional view for schematically illustrating a positioning mechanism included in a docking station and an electronic device which is yet to be mounted on the docking station according to a third embodiment;

FIG. 9A is an exemplary plan view of the positioning mechanism included in the docking station in a state where operation elements are yet to be pressed in the third embodiment;

FIG. 9B is an exemplary plan view of the positioning mechanism included in the docking station in a state where the operation elements are already pressed in the third embodiment;

FIG. 10 is an exemplary vertical cross-sectional view for schematically illustrating the positioning mechanism included in the docking station and the electronic device in a state where the operation elements are pressed by the electronic device and interlocking members are released from the lock applied by second locking mechanisms in the third embodiment;

FIG. 11 is an exemplary vertical cross-sectional view for schematically illustrating the positioning mechanism included in the docking station and the electronic device in a state where the operation elements are further pressed by the electronic device and pins are released from the lock applied by locking mechanisms in the third embodiment;

FIG. 12 is an exemplary vertical cross-sectional view for schematically illustrating the positioning mechanism included in the docking station and the electronic device mounted on the docking station in the third embodiment;

FIG. 13A is an exemplary plan view of a positioning mechanism included in a docking station in a state where operation elements are yet to be pressed according to a fourth embodiment;

FIG. 13B is an exemplary plan view of the positioning mechanism included in the docking station in a state where the operation elements are already pressed in the fourth embodiment;

FIG. 14 is an exemplary plan view for schematically illustrating a docking station according to a fifth embodiment; and

FIG. 15 is an exemplary side view for schematically illustrating a pin unit to be mounted on the docking station in the fifth embodiment.

### DETAILED DESCRIPTION

In general, according to one embodiment, a docking station comprises a main body, a pin, an operation element, a locking mechanism, and a lock releasing mechanism. An electronic device is mounted on the main body. The pin is supported on the main body in a protrudable-retractable manner. The operation element is supported on the main body in a protrudable-retractable manner. The locking mechanism is configured to lock the pin in a protruding position. The lock releasing mechanism is configured to unlock the pin locked by the locking mechanism in response to the pressing of the operation element in a direction in which the operation element is retracted by the electronic device. A tip of the pin in the protruding position is located at a higher level than a tip of the operation element in a protruding position. The operation element is located adjacent to the pin.

In exemplary and non-limiting embodiments described below, like constituent elements are referred to by like reference numerals, and repetition is avoided in the explanation of such constituent elements.

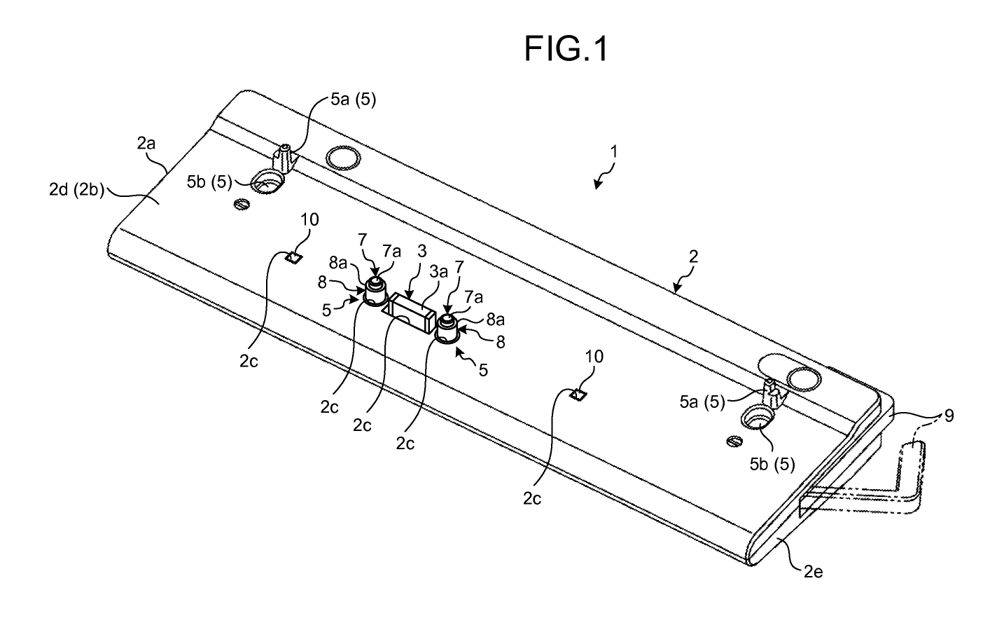

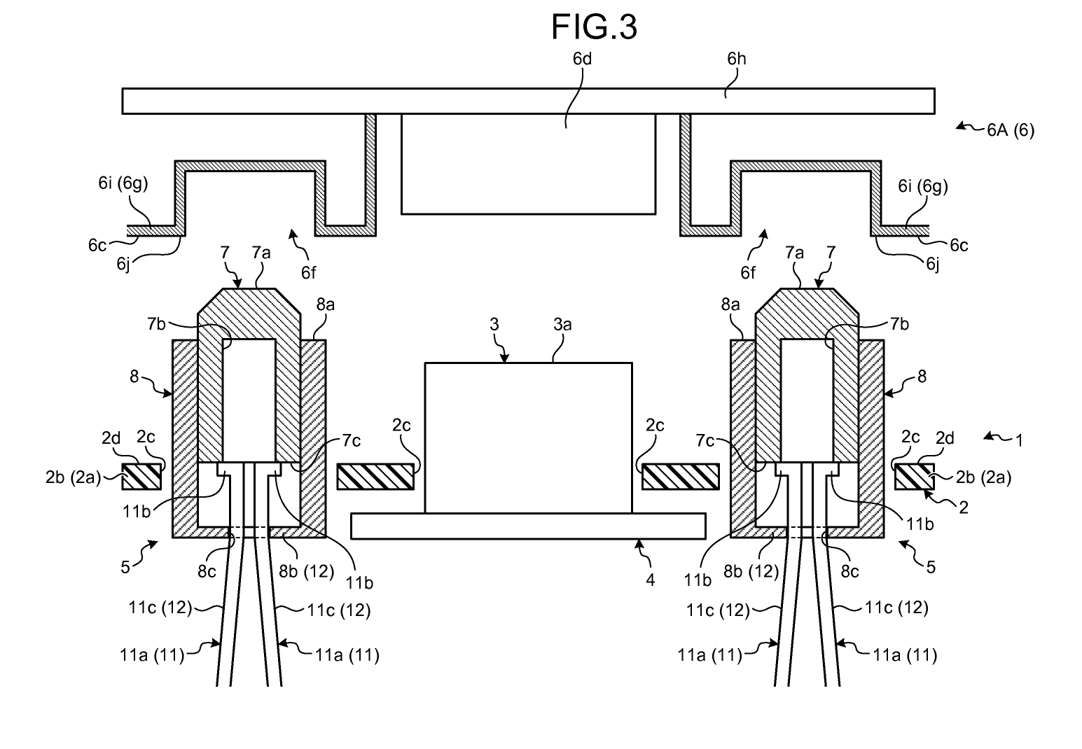

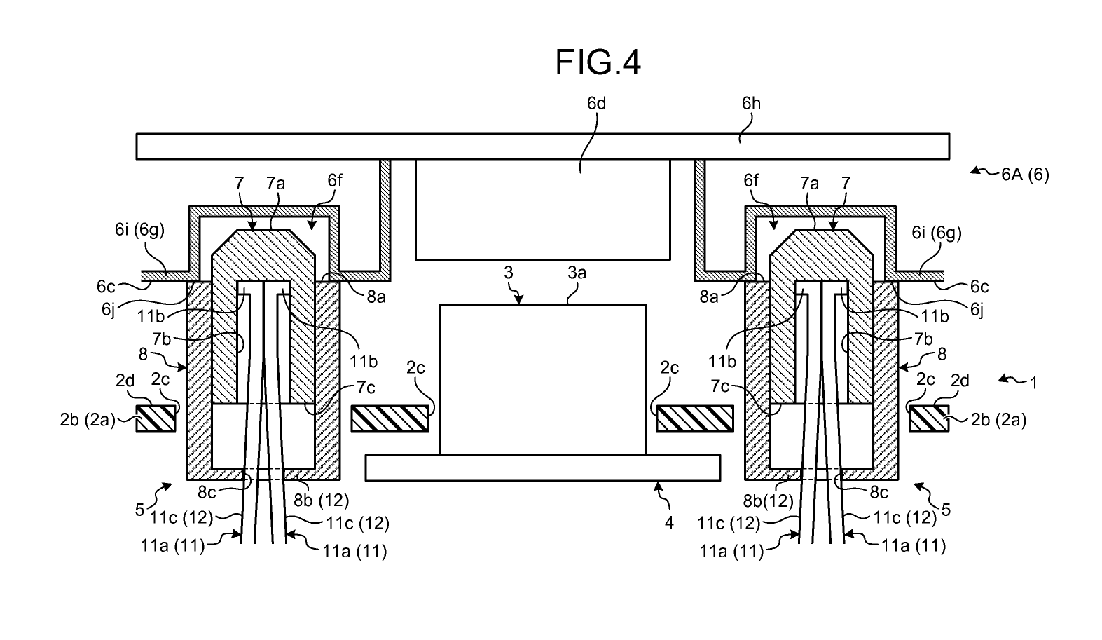

As illustrated in FIG. 1, according to a first embodiment, a docking station 1 functioning as a positioning apparatus comprises a main body 2 having the appearance of an elongated and flat rectangular parallelepiped. The main body 2 comprises a housing 2a as its outer block. The docking station 1 is used in a state where the main body 2 is placed on a placing member such as a desk. As illustrated in FIGS. 3 and 4, the housing 2a houses a circuit board 4 having electronic components such as a connector 3 mounted thereon and houses a portion of a positioning mechanism 5.

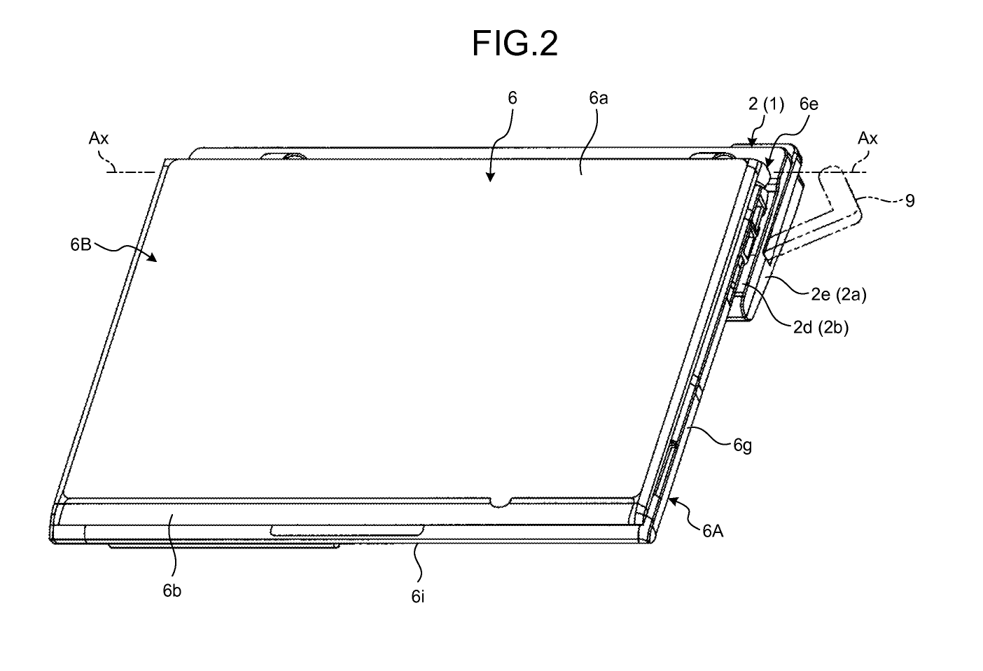

As illustrated in FIG. 2, in the first embodiment, a notebook personal computer 6 as an example of an electronic device has a rear margin portion 6a on the rear side in the depth direction of the personal computer 6. The rear margin portion 6a is placed on a top wall 2b of the housing 2a of the docking station 1. Besides, the personal computer 6 has a front margin portion 6b on the front side in the depth direction of the personal computer 6. The front margin portion 6b is directly placed on a placing member such as a desk. Thus, the personal computer 6 is placed on the placing member in a tilted manner in which the rear margin portion 6a on the rear side in the depth direction is raised by the docking station 1. From FIGS. 1 and 2, it is clear that the main body 2 of the docking station 1 of the first embodiment has an elongated shape along the width direction of the personal computer 6.

As illustrated in FIG. 1, a plurality of through holes 2c are formed on the top wall 2b of the housing 2a of the main body 2. Through the through holes 2c, the connector 3 functioning as a joining member, positioning pins 7, and operation elements 8 protrude from an upper face 2d of the top wall 2b. On the upper face 2d are provided protrusions 5a and recesses 5b that fit or engage with convex-concave portions (not illustrated) formed on a rear face 6c (see FIGS. 3 and 4) of the personal computer 6. With the pins 7 and the operation elements 8, the protrusions 5a and the recesses 5b also constitute the positioning mechanism 5. When the personal computer 6 is correctly placed on the main body 2, the connector 3 is connected to a connector 6d (see FIGS. 3 and 4) located on the rear face 6c of the personal computer 6.

On a side wall 2e of the housing 2a is located an eject lever 9 that serves as an operating member. When operated by the user, the eject lever 9 moves rotationally in the direction away from the side wall 2e. Due to that movement, eject pins 10, which move together with the eject lever 9 via an interlocking member (not illustrated) housed in the housing 2a, protrude from the upper face 2d through the through holes 2c and push up the rear face 6c of the personal computer 6. As a result, the personal computer 6 moves away from the upper face 2d of the main body 2. At that time, the connector 3 and the connector 6d of the personal computer 6 are disconnected from each other.

The connection of the connectors 3 and 6d enables the personal computer 6 to receive power supply from the docking station 1 for recharging a built-in battery and performing operations. Besides, through the connectors 3 and 6d, the personal computer 6 communicates various types of signals (communication signals, image signals, audio signals) with the docking station 1.

The personal computer 6 comprises a flat rectangular first main body 6A and a flat rectangular second main body 6B. The first main body 6A and the second main body 6B are connected via a hinge mechanism 6e to be relatively rotatable about a rotation axis Ax between an open state (not illustrated) and a folded state illustrated in FIG. 2.

The first main body 6A is provided with input modules such as a keyboard, or click buttons, or a pointing device (not illustrated), while the second main body 6B is provided with a display panel (not illustrated) such as a liquid crystal display (LCD) as a display device (component). In the open state of the personal computer 6, the keyboard, the pointing device, the click buttons, and the display screen of the display panel are exposed to the user so that the user can use them. On the other hand, in the folded state, the keyboard, the pointing device, the click buttons, and the display panel are hidden by the housing. In the first embodiment, even while being mounted on the docking station 1, the personal computer 6 can be opened for use by the user.

As illustrated in FIG. 1, the pins 7 constituting part of the positioning mechanism 5 are arranged on both sides, one on either side, in the longitudinal direction of the connector 3. In the first embodiment, the pins 7 function not only as positioning members for positioning the personal computer 6 but also as protective members for protecting the connector 3. In that regard, as illustrated in FIG. 3, tips (fore-ends) 7a of the pins 7 in the protruding position are positioned at a higher level than a tip 3a of the connector 3. This prevents the bottom wall of the personal computer 6 and other components from coming in contact with the connector 3.

However, if the configuration is such that the pins 7 are housed in recesses 6f formed on the rear face 6c of the personal computer 6 as protruding higher than the connector 3, the recesses 6f need to be deeper. If the recesses 6f are deeper, then the space inside a housing 6g of the personal computer 6 becomes narrow. That may cause inconveniences such as a decrease in the degree of freedom in the layout of the electronic components or a circuit board 6h inside the housing 6g, or a decrease in the mounting density of the electronic components. With regard to that issue, in the first embodiment, the pins 7 are configured to be protrudable-retractable so that they can be housed in the recesses 6f as being retracted (immersed state). That makes it possible to form the recesses 6f to be shallower.

To achieve the protruding-retracting motion of each pin 7 in the first embodiment, as illustrated in FIG. 2, in the housing 2a are provided a locking mechanism 11, which locks the corresponding pin 7 in the protruding position, and a lock releasing mechanism 12, which unlocks the corresponding pin 7 locked by the locking mechanism 11. The lock releasing mechanisms 12 release the respective pins 7 from the locked state, which is forced by the respective locking mechanisms 11, in response to the pressing of the operation elements 8 in a direction in which it is retracted by the personal computer 6 as a component. That is, in the normal state, the locking mechanisms 11 retain the tips 7a of the pins 7 in the protruding position at a higher level than the tip 3a of the connector 3. As the personal computer 6 is moved closer to the main body 2, the operation elements 8 is pressed by the rear face 6c (a bottom wall 6i) of the personal computer 6 and the lock releasing mechanisms 12 make the pins 7 retract.

However, consider a case when a component (in the first embodiment, the personal computer 6) to be mounted (or to be placed, to be abutted, or to be connected) is out of alignment or is tilted with respect to the main body 2 and does not come close the docking station 1 with a correct position or a correct orientation, or consider a case when the operation elements 8 are accidentally pressed by an object other than the component to be mounted or accidentally pressed by the fingers of the user. In such cases, it is desirable that the pins 7 do not retract as much as possible. In that regard, in the first embodiment, as illustrated in FIGS. 3 and 4, the operation elements 8 are located adjacent to the pins 7 and the tips 7a of the pins 7 in the protruding position are located at a higher level than tips 8a of the operation elements 8 in the protruding position. That makes it possible to prevent the operation elements 8 from being accidentally pressed. That is, if the operation elements 8 and the pins 7 are positioned apart from each other, there is a possibility that the operation elements 8 are accidentally pressed by an out-of-alignment component or by a tilted component, which may lead to retraction of the pins 7. On the other hand, in the first embodiment, since the operation elements 8 and the pins 7 are adjacently located, the pins 7 prevent the operation elements 8 from being pressed by a component or by another object.

More specifically, in the first embodiment, as illustrated in FIGS. 3 and 4, the operation elements 8 are formed to be in the shape of bottomed cylinders with upward openings (i.e., with openings along the normal direction of the upper face 2d of the main body 2). In contrast, the pins 7 are formed to be in the shape of bottomed cylinders with downward openings (i.e., with openings along the opposite direction to the normal direction of the upper face 2d of the main body 2) and are housed inside the cylinders of the respective operation elements 8 in a vertically slidable manner. Thus, in the first embodiment, the operation elements 8 not only are located adjacent to the pins 7 but also encircle the periphery of the pins 7. Meanwhile, the pins 7 and the operation elements 8 can be made of a metallic material or a synthetic resin material.

The operation elements 8 are supported in a vertically movable manner on the housing 2a of the main body 2. The operation elements 8 are not only biased upward (i.e., in the protruding direction) with respect to the main body 2 or with respect to the respective pins 7 by biasing mechanisms such as coil springs (not illustrated) but are also prevented from protruding further upward than their protruding positions illustrated in FIG. 3 by latching mechanisms (not illustrated). Similarly, the pins 7 are not only biased upward (i.e., in the protruding direction) with respect to the main body 2 or with respect to the respective the operation elements 8 by biasing mechanisms such as coil springs (not illustrated) but are also prevented from protruding further upward than their protruding positions illustrated in FIG. 3 by latching mechanisms (not illustrated).

The locking mechanism 11 comprises a plurality of arms 11a that are fixed to, for example, the housing 2a of the main body 2 and that extend upward, and a locking portion 11b formed at the fore-ends of the arms 11a. The arms 11a pass through a through hole 8c formed in a bottom wall 8b of the corresponding operation element 8, while the locking portion 11b is arranged inside the cylinder of the corresponding operation element 8 as protruding in the outward radial direction at the end of the arms 11a. The arms 11a are biased along the outward radial direction due to their own elasticity or due to biasing mechanisms such as coil springs (not illustrated). The arms 11a are locked at the inner peripheral face (the bottom wall 8b) of the corresponding through hole 8c in such a way that they cannot not move in the outward radial direction farther than the positions illustrated in FIG. 3. As illustrated in FIG. 3, in the normal state when the operation elements 8 are not pressed, the arms 11a extend in the outward radial direction and the locking portion 11b does not enter an inner cylinder 7b of the corresponding pin 7 but remains positioned beneath a bottom face 7c of the corresponding pin 7. Thus, in this normal state, the locking portion 11b prevents the corresponding pin 7 from moving downward (i.e., moving in the retracting direction). That is, each pin 7 is retained in the protruding position by the corresponding locking mechanism 11.

The arm 11a has a tilted portion 11c that extends in the outward radial direction toward downward. The tilted portions 11c are formed beneath the bottom wall 8b of the corresponding operation element 8. Thus, when the operation elements 8 move downward upon being pressed, the bottom wall 8b of each operation element 8 presses the tilted portions 11c of the corresponding arms 11a in the inward radial direction, and thereby the arms 11a and the locking portion 11b of each locking mechanism 11 move in the inward radial direction. Thus, the locking portion 11b can enter the inner cylinder 7b of the corresponding pin 7, and the corresponding pin 7 can move downward (i.e., retract). As a result, the restriction on the downward movement of the pins 7 applied by the locking portion 11b is lifted. That is, the pins 7 are released from the lock by the respective locking mechanisms 11 as being in the protruding position. In the first embodiment, the bottom wall 8b of each operation element 8 and the tilted portions 11c of the arms 11a corresponding to the operation element 8 constitute the lock releasing mechanism 12.

In the state illustrated in FIG. 3, the tips 7a of the pins 7 that are locked by the respective locking mechanisms 11 as being in the protruding position are located at a higher level than the tip 3a of the connector 3. In that state, when the user holds the personal computer 6 with his/her hands and moves it down to the correct position (correctly-determined position), each pin 7 is inserted in the corresponding recess 6f and, as illustrated in FIG. 4, margin portions 6j of the recesses 6f in the bottom wall 6i of the personal computer 6 press the operation elements 8 upward. As a result, the pins 7 are released from the lock by the respective locking mechanisms 11 as being in the protruding position. Hence, the pins 7 become retractable. When the personal computer 6 is moved down to the position at which it is placed on the main body 2, the connector 6d is connected to the connector 3. Then, each pin 7 retracts upon being pressed by a bottom wall 6k of the corresponding recess 6f.

As described above, according to the first embodiment, the operation elements 8 are located adjacent to the pins 7 and the tips 7a of the pins 7 in the protruding position are located at a higher level than the tips 8a of the operation elements 8 in the protruding position. Therefore, the pins 7 prevent the operation elements 8 from being accidentally pressed by another component or object. Moreover, since each pin 7 and the corresponding operation element 8 are passed through the same through hole 2c, it becomes possible to reduce the time and efforts needed to manufacture the docking station 1. Besides, regarding the pins 7, the operation elements 8, the locking mechanisms 11, the lock releasing mechanisms 12, and the supporting members (not illustrated), configuring a module (not illustrated) by integrating those constituent elements further reduces the time and efforts needed to manufacture the docking station 1.

Moreover, according to the first embodiment, each operation element 8 encircles the periphery of the corresponding pin 7. Hence, when the main body 2 and the personal computer 6 are correctly positioned, the margin portions 6j of the recesses 6f in the bottom wall 6i of the personal computer 6 press the operation elements 8 downward. In the correctly-positioned state, the operation elements 8 are pressed by the personal computer 6 with relative ease, while in the incorrectly-positioned state, the pins 7 prevent the operation elements 8 from being accidentally pressed.

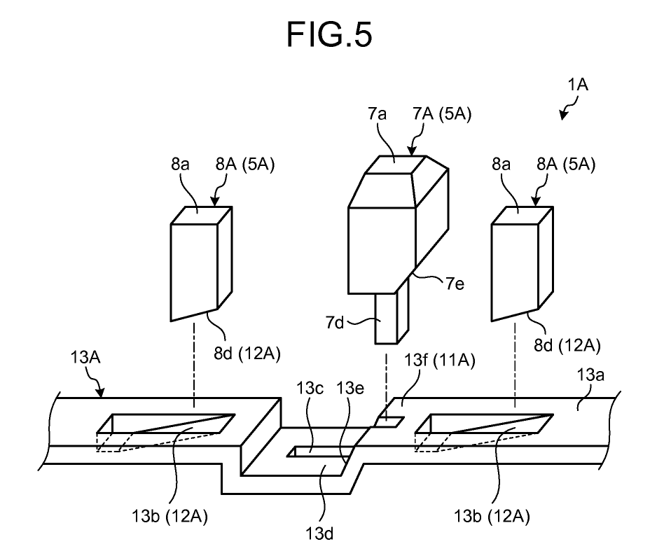

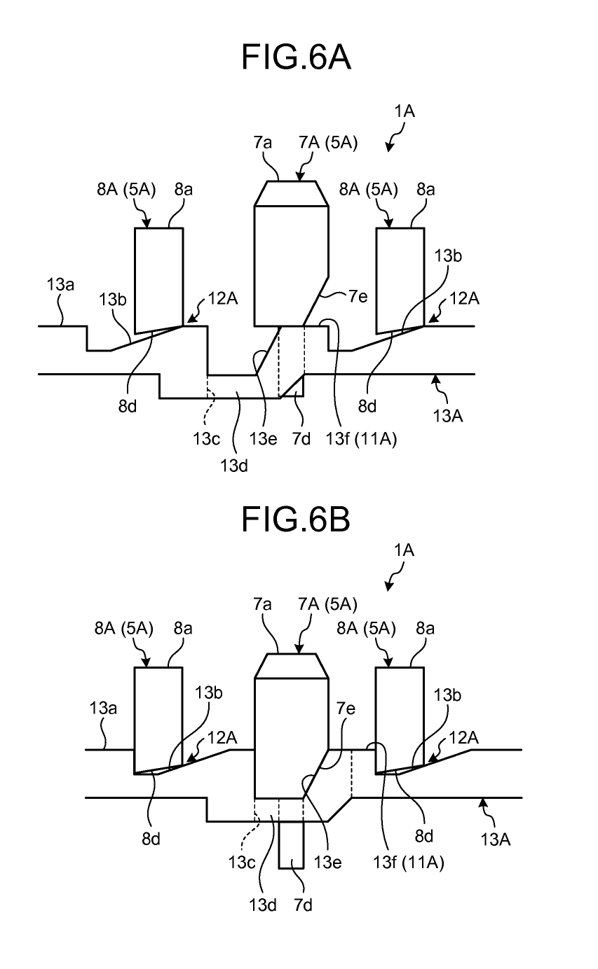

As illustrated in FIGS. 5 to 7, according to a second embodiment, a docking station 1A comprises pins 7A and operation elements 8A constituting a positioning mechanism 5A and comprises an interlocking member 13A that operates together with the pins 7A and the operation elements 8A. The interlocking member 13A is housed in a transversely lying manner (in the direction perpendicular to the protruding-retracting direction of the pins 7A and the operation elements 8A) inside the housing of the main body (not illustrated) of the docking station 1A. Moreover, the interlocking member 13A is formed to be belt-like and plate-like in shape from a synthetic resin material or a metallic material, and is reciprocatably supported on the main body in the longitudinal direction (transverse direction) thereof. In the second embodiment too, the pins 7A and the operation elements 8A are supported on the main body in a protrudable-retractable manner, and are biased in their protruding directions. A locking mechanism (not illustrated) is located to prevent the pins 7A and the operation elements 8A from moving upward than the respective predetermined protruding positions. In the protruding position, the pins 7A and the operation elements 8A protrude from the upper face of the main body. The main body prevents the pins 7A and the operation elements 8A from moving in the transverse direction. In FIGS. 5 to 7, for the sake of convenience in explanation, the pin 7A and the corresponding operation element 8 are illustrated to be slightly spaced apart. However, in practice, each pin 7A and the corresponding operation element 8 are located in a mutually adjacent manner. More specifically, for example, by shifting the positions of the pins 7A and the respective operation elements 8 in the direction perpendicular to the plane of paper of FIG. 6, the pins 7A and the respective operation elements 8 can be located adjacent in the direction perpendicular to the plane of paper of FIG. 6.

In the interlocking member 13A, tilted portions 13b are formed on a top face 13a at the positions facing the operation elements 8A. At the lower ends of the operation elements 8A, tilted portions 8d are formed that slide into the tilted portions 13b. Thus, a downward pressing operation on the operation elements 8A is transformed into the movement in the longitudinal direction (in the second direction, rightward movement) of the interlocking member 13A due to the sliding of the tilted portions 8d into the tilted portions 13b.

Each pin 7A comprises a slider 7d, which is housed in a longitudinally slidable manner in a through hole 13c that is formed correspondingly in a rail portion 13d of the interlocking member 13A. Each rail portion 13d is formed in between the upper end and the lower end of a tilted portion 13e, which is formed on the interlocking member 13A corresponding to each pin 7A. In the second embodiment, the tilted portions 13e are tilted downward and leftward in FIGS. 5 and 6 as with the tilted portions 13b corresponding to the operation elements 8A.

In such a configuration, when the operation elements 8A are pressed downward by a component such as the personal computer 6 (see FIG. 2), the tilted portions 13e move rightward in FIGS. 5 and 6. As a result, as illustrated in FIG. 6B, the tilted portions 13e move to the right side thereby enabling the respective pins 7A to retract downward. Within the movable range of the tilted portions 13e, the sliders 7d of the respective pins 7A can slide inside the through holes 13c formed in the respective rail portions 13d. Thus, in the second embodiment, upper ends 13f of the rail portions 13d correspond to the locking mechanisms 11 for locking the pins 7A in the protruding position, while the tilted portions 8d of the operation elements 8A, the tilted portions 13b of the interlocking member 13A into which the tilted portions 8d can slide, and the interlocking member 13A collectively correspond to the lock releasing mechanisms 12.

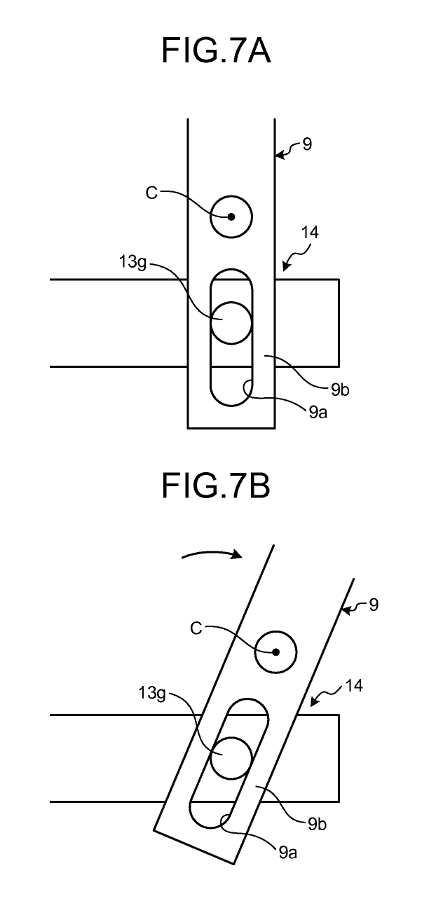

Moreover, in the second embodiment, the pins 7A and operation elements 8A serve as eject pins. That is, as illustrated in FIG. 7, the interlocking member 13A is connected to the eject lever 9 via a linking mechanism 14. The linking mechanism 14 is configured from a slider 13g of the interlocking member 13A and a rail portion 9b on the eject level 9 in which an elongated through hole 9a is formed for housing the slider 13g in a longitudinally movable manner. When the user rotates the eject lever 9 around a rotation center C from the position illustrated in FIG. 7A to the position illustrated in FIG. 7B, the interlocking member 13A moves leftward in FIGS. 5 and 6. Consequently, the tilted portions 13b and 13e on the interlocking member 13A respectively press the tilted portions 8d of the operation elements 8A and the tilted portions 7e of the pins 7A, and thereby the operation elements 8A and the pins 7A protrude upward as illustrated in FIG. 6A. The protruding pins 7A and the protruding operation elements 8A push up the rear face 6c (the bottom wall 6i) of the personal computer 6. As a result, the personal computer 6 moves away from the main body. In the second embodiment, since the pins 7A and the operation elements 8A can be used as eject pins, the configuration becomes simpler as compared to a configuration in which eject pins are separately provided. This reduces the time and efforts needed to manufacture the docking station 1A.

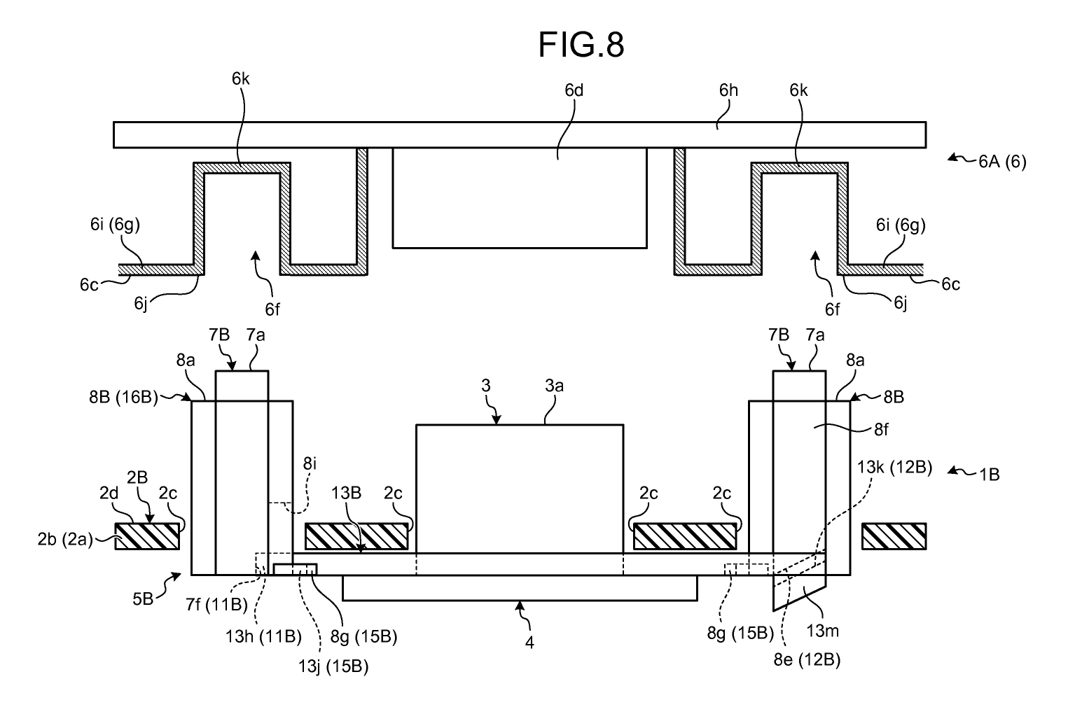

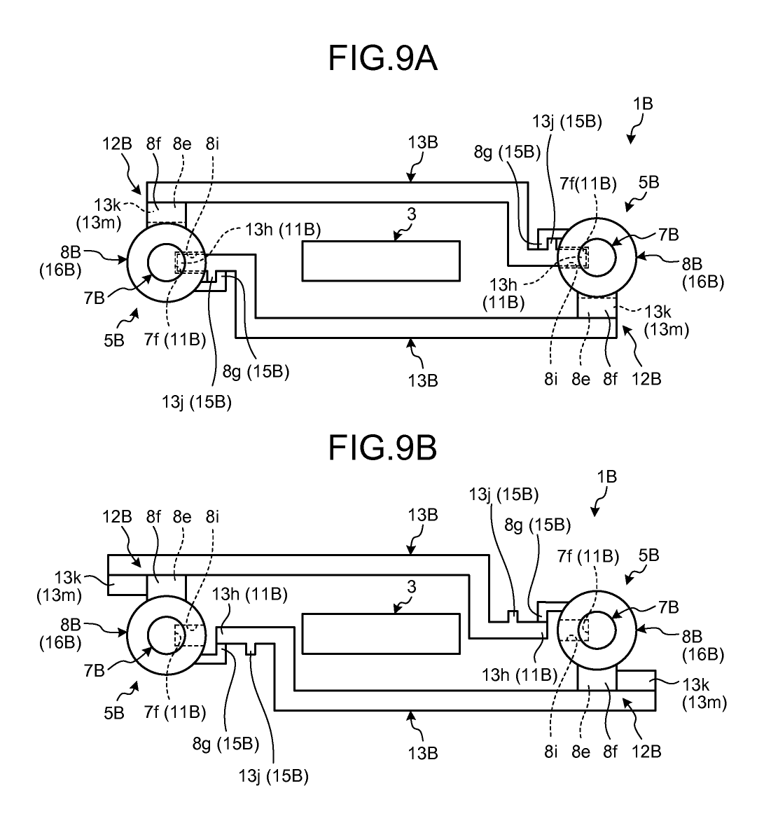

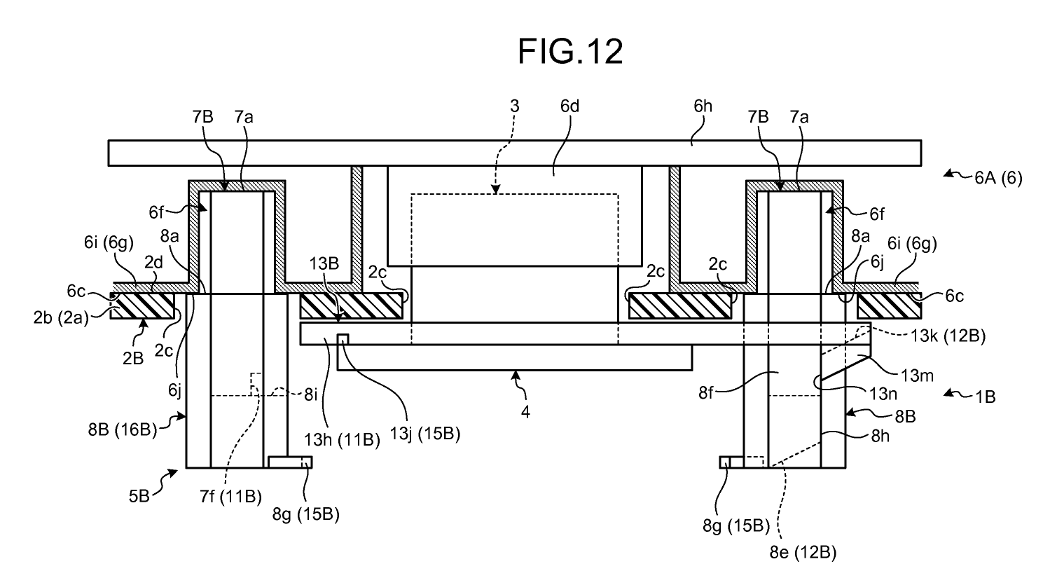

As illustrated in FIGS. 8 to 12, according to a third embodiment, a docking station 1B comprises pins 7B and operation elements 8B constituting a positioning mechanism 5B and comprises interlocking members 13B that operate together with the pins 7B and the operation elements 8B. The interlocking members 13B are housed in a transversely lying manner (in the direction perpendicular to the protruding-retracting direction of the pins 7B and the operation elements 8B) inside the housing 2a of a main body 2B of the docking station 1B. In the third embodiment, the interlocking members 13B are formed to be belt-like and plate-like in shape, and are reciprocatably supported on the main body 2B in the longitudinal direction (transverse direction) thereof. In the third embodiment, as illustrated in FIG. 9, the docking station 1B comprises two combinations of the pins 7B, the operation elements 8B, and the interlocking members 13B arranged in point symmetry. The two interlocking members 13B are located on both sides in the short direction of the connector 3 and extend along the longitudinal direction of the connector 3. Meanwhile, the pins 7B and the operation elements 8B are restricted from lateral movement by the main body 2B.

As illustrated in FIGS. 8 and 9, the operation elements 8B are formed to be cylindrical in shape, while the pins 7B are formed to be columnar in shape and are housed in a vertically reciprocatable manner inside the cylinders of the respective operation elements 8B. Thus, in the third embodiment also, the operation elements 8 not only are located adjacent to the pins 7B but also encircle the periphery of the pins 7B.

The operation elements 8B are supported in a vertically movable manner on, for example, the housing 2a of the main body 2B. The operation elements 8B are not only biased upward (i.e., in the protruding direction) with respect to the main body 2B or with respect to the respective pins 7 by biasing mechanisms such as coil springs (not illustrated) but are also prevented from protruding further upward than their protruding positions illustrated in FIG. 8 by latching mechanisms (not illustrated). Similarly, the pins 7B are not only biased upward (i.e., in the protruding direction) with respect to the main body 2B or with respect to the respective operation elements 8B by biasing mechanisms such as coil springs (not illustrated) but are also prevented from protruding further upward than their protruding positions illustrated in FIG. 8 by latching mechanisms (not illustrated).

Locking mechanisms 11B to lock the pins 7B in the protruding position comprise part of the interlocking members 13B. In the third embodiment, one end in the longitudinal direction of each interlocking member 13B serves as an engaging portion 13h that restricts the corresponding pin 7B from being pressed toward the inside of the housing 2a (downward, in the retracting direction). At the lower end of each pin 7B, a notch opening toward the lower side as well as toward the outside is formed as a portion for engagement 7f with which the corresponding engaging portion 13h engages. Besides, at the lower end of each operation element 8B, a notch 8i opening toward the lower side is formed to avoid interference with the corresponding engaging portion 13h. In the third embodiment, the engaging portions 13h correspond to the locking mechanisms 11B. The interlocking members 13B are biased by biasing mechanisms such as coil springs (not illustrated) in the direction in which the engaging portions 13h of the locking mechanisms 11B enter the portions for engagement 7f.

Lock releasing mechanisms 12B to release the pins 7B from the locked state applied by the locking mechanisms 11B also comprise part of the interlocking members 13B. In the third embodiment, on the other end in the longitudinal direction of each interlocking member 13B, the lock releasing mechanism 12B is formed that, with downward movement of the corresponding operation element 8B, moves the corresponding engaging portion 13h in the outward radial direction, i.e., in the direction of releasing the engagement between the corresponding engaging portion 13h and the portion for engagement 7f. On each lock releasing mechanism 12B, a tilted portion 8e is formed below a protrusion 8f that protrudes from the lower end of the corresponding operation element 8B in the outward radial direction. The more the engaging portion 13h of each interlocking member 13B moves away from the corresponding portion for engagement 7f (i.e., moves in the right direction regarding the lower interlocking member 13B illustrated in FIGS. 9A and 9B, or moves in the left direction regarding the upper interlocking member 13B illustrated in FIGS. 9A and 9B), the more it tilts toward the protruding direction of the corresponding operation element 8B (i.e., tilts upward). Meanwhile, each protrusion 8f extends along the axial direction of the corresponding operation element 8B and, in the third embodiment, is located over the area from the lower end to the upper end of the corresponding operation element 8B. On the other hand, at the bottom of a protrusion 13m that protrudes from the other end of each interlocking member 13B toward the inward radial direction of the corresponding operation element 8B, a tilted portion 13k is formed that slides from opposite at the lower side of the corresponding tilted portion 8e. In such a configuration, when the operation elements 8B retract to the inside of the housing 2a upon being pressed, the interlocking members 13B move in the longitudinal direction due to the sliding of the tilted portions 8e and 13k, and the engaging portions 13h move away from the respective portions for engagement 7f. Hence, in the third embodiment, the tilted portions 8e and 13k correspond to the lock releasing mechanisms 12B. Meanwhile, each interlocking member 13B corresponds to a second interlocking member.

As is clear from FIG. 9, in the third embodiment, a pair of the pin 7B and the corresponding adjacent operation element 8B is located on both sides the longitudinal direction in such a way that the connector 3 is sandwiched therebetween. Besides, in the third embodiment, the lock of one of the two pins 7B (e.g., the pin 7B on the left side in FIG. 9A or 9B) is released via one of the interlocking members 13B (e.g., the lower interlocking member 13B in FIG. 9A or 9B) when the operation element 8B located adjacent to the other of the two pins 7B (e.g., the pin 7B on the right side in FIG. 9A or 9B) is pressed. Similarly, the lock of the other of the two pins 7B (e.g., the pin 7B on the right side in FIG. 9A or 9B) is released via one of the interlocking members 13B (e.g., the upper interlocking member 13B in FIG. 9A or 9B) when the operation element 8B located adjacent to the other pin 7B (e.g., the pin 7B on the left side in FIG. 9A or 9B) is pressed. Due to such a configuration, if only one of the operation elements 8B is locally and accidentally pressed by a component, an objet, or a finger, the pin 7B located adjacent to that pressed operation element 8B is not unlocked. For this reason, it becomes possible to further prevent the situation in which local and accidental pressing leads to retraction of the operation element 8B and the corresponding pin 7B, and eventually the connector 3 is affected. Besides, regarding the component (in the third embodiment, the personal computer 6) to be mounted (or to be placed, to be abutted, or to be connected), since the two pins 7B are unlocked when both of the operation elements 8B are pressed, the possibility of any malfunctioning condition is eliminated. That is, in the third embodiment, the two pins 7B in the protruding position are unlocked only when both the operation elements 8B are pressed. Such a configuration enables prevention of accidental unlocking of the pins 7B.

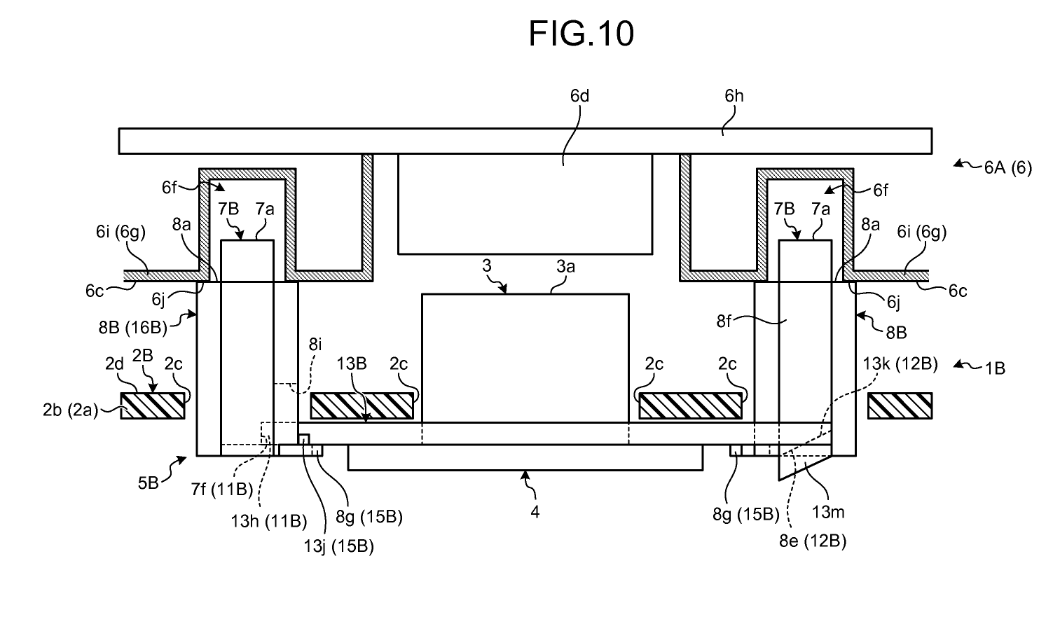

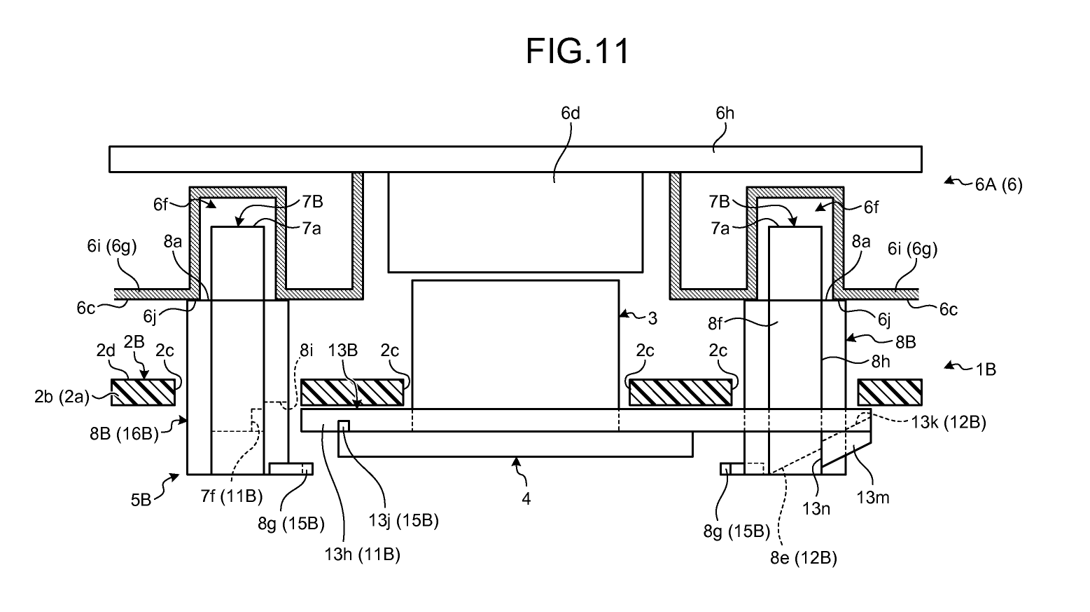

Moreover, in the third embodiment, regarding one of the two operation elements 8B (first operation element 8B), the movement of the corresponding interlocking member 13B that occurs due to the pressing of the first operation element 8B is controlled by the other operation element (second operation element 8B). More specifically, at that end of the interlocking member 13B on which the engaging portion 13h is formed, a portion for engagement 13j is formed in the transverse direction (perpendicular to the exit direction of the engaging portion 13h). Besides, on the corresponding operation element 8B, an engaging portion 8g is formed for engaging the portion for engagement 13j in the exit direction of the engaging portion 13h. As illustrated in FIG. 10, when the operation elements 8B move downward upon being pressed, the portions for engagement 13j are released from engagement by the respective engaging portions 8g. Thus, in the third embodiment, each engaging portion 8g and the corresponding portion for engagement 13j constitute a second locking mechanism 15B. As illustrated in FIG. 10, when the operation elements 8B are slightly pressed, the second locking mechanisms 15B are unlocked first. Thus, in the third embodiment, each operation element 8B corresponds to a second lock releasing mechanism 16B. As illustrated in FIG. 11, when the operation elements 8B are further pressed, the locking mechanisms 11B are unlocked by the respective lock releasing mechanisms 12B. Thus, in the third embodiment, the pins 7B are unlocked only when both the operation elements 8B are pressed but not when only one of the operation elements 8B is pressed. Due to such a configuration, it becomes possible to further prevent the pins 7B from being accidentally unlocked. Moreover, in the third embodiment, to ensure that the locks applied by the locking mechanisms 11B are released by the respective lock releasing mechanisms 12B only after the locks applied by the second locking mechanisms 15B are released by the respective second lock releasing mechanisms 16B, in the normal state, the tilted portions 8e and 13k constituting each lock releasing mechanism 12B are spaced apart from each other as illustrated in FIG. 8. Subsequently, as illustrated in FIG. 10, only after the locks applied by the second locking mechanisms 15B are released by the pressing of the operation elements 8B serving as the second lock releasing mechanisms 16B, the tilted portions 8e and 13k constituting each lock releasing mechanism 12B abut against each other and the sliding thereof leads to the unlocking of the pins 7B locked by the respective locking mechanisms 11B.

As illustrated in FIGS. 9B and 11, when the personal computer 6 is moved close to the main body 2B, the sliding of the tilted portions 8e and 13k constituting each lock releasing mechanism 12B causes the protrusion 13m of the corresponding interlocking member 13B to move by a predetermined distance in the transverse direction. As a result, with respect to the protrusion 8f of each operation element 8B, the corresponding protrusion 13m moves around to the opposite side of the engaging portion 13h so that the protrusions 13m and 8f are engaged in the longitudinal direction of the corresponding interlocking member 13B. Thus, in the third embodiment, when the locks applied by the locking mechanisms 11 are released by the respective lock releasing mechanisms 12, the protrusions 8f prevent the respective protrusions 13m, i.e., the respective interlocking members 13B, from moving toward the respective engaging portions 13h. As a result, the released state does not return to the locking state applied by the locking mechanisms 11B. Besides, as illustrated in FIG. 11, when the operation elements 8B are pressed downward while the protrusions 13m and the respective protrusions 8f are in the engaged state, a sliding surface 13n of each protrusion 13m and a sliding surface 8h of the corresponding protrusion 8f slide against each other.

When the user moves the personal computer 6 closer to the main body 2B, the bottom wall 6i is placed on the top wall 2b and the connectors 3 and 6d are connected as illustrated in FIG. 8. The pins 7B are housed in the respective recesses 6f, and the tip 7a of each pin 7B abuts against the bottom wall 6k of the corresponding recess 6f.

According to the third embodiment, each lock releasing mechanism 12B releases the lock of the corresponding pin 7B locked by the corresponding locking mechanism 11B in response to the pressing of the operation element 8B that is located adjacent to the other pin 7B than the pin 7B under consideration. Hence, even if one of the operation elements 8B is locally and accidentally pressed, the pin 7B located adjacent to that pressed operation element 8B is not unlocked. For this reason, it becomes possible to prevent the situation in which local and accidental pressing leads to retraction of the operation element 8B and the corresponding pin 7B, and eventually causes interference between the connector 3 and, for example, a component, an objet, or a finger.

Moreover, in the third embodiment, the second locking mechanisms 15B control the interlocking operation of the respective interlocking members 13B, which use the respective lock releasing mechanisms 12B to release the lock on the respective pins 7B in conjunction with the pressing of one of the operation elements 8B (e.g., first operation element 8B). Then, the second lock releasing mechanisms 16B release the lock of the interlocking members 13B, which have been locked by the respective second locking mechanisms 15B, in response to the pressing of the other operation element 8B (e.g., second operation element 8B). Thus, each pin 7B is unlocked only when both of the first operation element 8B and the second operation element 8B are pressed. For this reason, it becomes possible to prevent the situation in which local and accidental pressing of one of the operation elements 8B leads to retraction of the pins 7B, and eventually causes interference between the connector 3 and, for example, a component, an objet, or a finger.

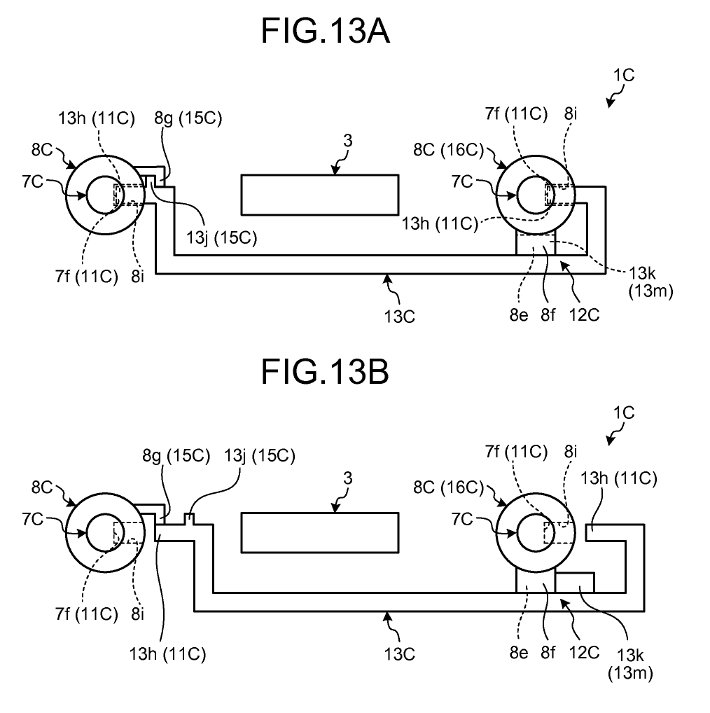

According to a fourth embodiment, a docking station 1C illustrated in FIG. 13 comprises pins 7C, operation elements 8C, locking mechanisms 11C, a lock releasing mechanism 12C, and a second lock releasing mechanism 16C, which are respectively identical to the pins 7B, the operation elements 8B, the locking mechanisms 11B, the lock releasing mechanisms 12B, and the second lock releasing mechanisms 16B according to the third embodiment. However, in the fourth embodiment, the locking mechanisms 11C corresponding to the two pins 7C are provided to a single interlocking member 13C. Moreover, the lock releasing mechanism 12C is provided to only one of the two operation elements 8C, while a second locking mechanism 15C and the second lock releasing mechanism 16C are provided to the other operation element 8C. The locking mechanisms 11C comprise the engaging portions 13h that are formed at both ends in the longitudinal direction of the interlocking member 13C and the portions for engagement 7f formed on the pins 7C corresponding to the engaging portions 13h. The lock releasing mechanism 12C comprises the tilted portion 8e that is formed on the protrusion 8f of one of the two operation elements 8C (in FIG. 13, the operation element 8C on the right side) and the tilted portion 13k that is formed correspondingly to the tilted portion 8e on the protrusion 13m of the interlocking member 13C. The second locking mechanism 15C comprises the engaging portion 8g formed on one of the two operation elements 8C (in FIG. 13, the operation element 8C on the left side) and the portion for engagement 13j formed correspondingly to the engaging portion 8g on the interlocking member 13C. The second lock releasing mechanism 16C comprises the operation element 8C on which the lock releasing mechanism 12C is not located (in FIG. 13, the operation element 8C on the left side). In the fourth embodiment also, each pin 7C and the corresponding operation element 8C constitute a portion of a positioning mechanism 5C.

According to the fourth embodiment, the plurality of pins 7C (in the fourth embodiment, the two pins 7C) locked by the respective locking mechanisms 11C are unlocked by the lock releasing mechanism 12C when one of the two operation elements 8C (in FIG. 13, the operation element 8C on the right side) is pressed. However, the interlocking member 13C locked by the second locking mechanism 15C is unlocked by the second lock releasing mechanism 16C when the other of the two operation elements 8C (in FIG. 13, the operation element 8C on the left side) is pressed. Hence, only when both the operation elements 8C are pressed, the lock releasing mechanism 12C operates effectively and releases the lock of the respective pins 7C locked by the locking mechanisms 11C. However, when only one of the two operation elements 8C (in FIG. 13, the operation element 8C on the right side) is pressed or when only the other operation element 8C (in FIG. 13, the operation element 8C on the left side) is pressed, the pins 7C locked by the respective locking mechanisms 11C are not unlocked. Thus, in the fourth embodiment also, each pin 7C is unlocked only when both of the first operation element 8C and the second operation element 8C are pressed. For this reason, it becomes possible to prevent the situation in which local and accidental pressing of one of the operation elements 8C leads to retraction of the pins 7C, and eventually causes interference between the connector 3 and, for example, a component, an objet, or a finger. Moreover, in the fourth embodiment, the functions identical to those described in the third embodiment can be executed with a smaller number of components.

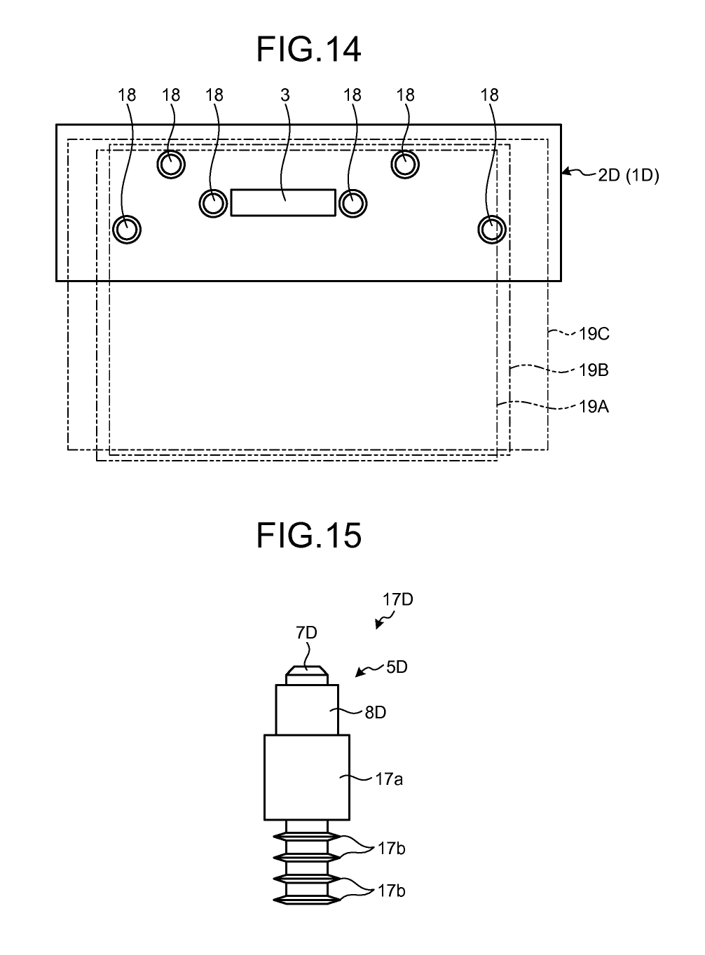

According to a fifth embodiment, in a docking station 1D illustrated in FIGS. 14 and 15, a main body 2D has a plurality of recesses 18 formed therein as illustrated in FIG. 14. In each recess 18, a pin unit 17D illustrated in FIG. 15 can be detachably inserted. Each pin unit 17D comprises a pin 7D and an operation element 8D, and constitutes a portion of a positioning mechanism 5D. Depending on which of a plurality of personal computers 19A to 19C is to be mounted on the docking station 1D, the user can alter the recesses 18 for inserting the pin units 17D. As a result, the same docking station 1D can be shared among the personal computers 19A to 19C. The pin unit 17D illustrated as an example in FIG. 15 can also be configured in such a way that a housing 17a houses the pin 7, the operation element 8, the locking mechanism 11, and the lock releasing mechanism 12 described in the first embodiment. In this case, the housing 17a is inserted in one of the recesses 18 and is fixed to the docking station 1D. Meanwhile, on the periphery of the housing 17a is formed an elastically deformable protrusion 17b. According to the fifth embodiment, even with a configuration in which detachably-insertable pins (individual components) are used instead of the pin units 17D, the docking station 1D can be shared among a plurality of electronic devices.

While the above embodiments are described as being applied to a docking station used for docking a notebook personal computer, they may be applicable to a docking station or a positioning apparatus for other electronic device such as a desktop computer, a personal digital assistant (PDA), a smartbook, a smartphone, and a cellular phone.

Regarding the docking station, the positioning mechanism, the electronic device, the personal computer, the component, the main body, the pin, the operation element, the locking mechanism, the lock releasing mechanism, the second locking mechanism, the second lock releasing mechanism, the interlocking member, the operating member, the positioning mechanism, and the mounting portion, the specifications (operating method, structure, shape, material, size, length, width, number, arrangement, position, operating direction, approaching/receding direction, etc.) can be suitably modified. Besides, on the main body, the pins and the operation elements can be supported either directly or indirectly via a predetermined member.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A docking station comprising:
a main body configured to support an electronic device;
a first pin supported on the main body in a protrudable-retractable manner, wherein the first pin is configured to move between a protruding position and a retracted position;
a first operation element supported on the main body in a protrudable-retractable manner, wherein the first operation element is configured to move between a protruding position and a retracted position;
a first locking mechanism configured to lock the first pin in the protruding position; and
a lock releasing mechanism configured to unlock the first pin in response to pressing of the operation element toward the retracted position, wherein
a tip of the first pin in the protruding position is higher than a tip of the first operation element in a protruding position, and
the first operation element is substantially adjacent to the first pin.

2. The docking station of claim 1, wherein the first operation element encircles a periphery of the first pin.

3. The docking station of claim 1, further comprising:
an interlocking member configured to cause the lock releasing mechanism to unlock the first pin in conjunction with the pressing of the operation element toward the retracted position; and
an operating member configured to move the interlocking member in a direction in which the first operation element protrudes.

4. The docking station of claim 1, further comprising:
a second operation element supported on the main body in a protrudable-retractable manner, wherein the second operation element is configured to move between a protruding position and a retracted position,
wherein the lock releasing mechanism is further configured to unlock the first pin in response to pressing of the second operation element toward the retracted position.

5. The docking station of claim 1, further comprising:
a second pin supported on the main body in a protrudable-retractable manner, wherein the second pin is configured to move between a protruding position and a retracted position;
a second operation element supported on the main body in a protrudable-retractable manner, wherein the second operation element is configured to move between a protruding position and a retracted position;
an interlocking member configured to cause the lock releasing mechanism to unlock the first pin in conjunction with pressing of the first operation element toward the retracted position;
a second locking mechanism configured to control interlocking operation of the second interlocking member; and
a second lock releasing member configured to unlock the second interlocking member locked by the second locking mechanism in response to pressing of the second operation element toward the retracted position.

6. The docking station of claim 1, further comprising:
one or more additional pins supported on the main body in a protrudable-retractable manner, wherein the one or more additional pins are each configured to move between a protruding position and a retracted position; and
one or more additional operation elements supported on the main body in a protrudable-retractable manner, wherein the one or more additional operation elements are each configured to move between a protruding position and a retracted position, and wherein the one or more additional operation elements are each substantially adjacent to a pin,
wherein the lock releasing mechanism is further configured to unlock the first pin in response to pressing of the one or more additional operation elements toward the retracted position.

7. The docking station of claim 1, wherein:
the main body comprises a plurality of mounting portions on which a positioning mechanism is mounted,
the positioning mechanism comprises the first pin, the first operation element, the first locking mechanism, and the lock releasing mechanism, and
the positioning mechanism is configured to be replaceable.

8. The docking station of claim 7, wherein the mounting portions are positioned in correspondence with a plurality of electronic devices.

9. A positioning apparatus comprising:
a main body located near or in contact a component;
a pin supported on the main body in a protrudable-retractable manner, wherein the pin is configured to move between a protruding position and a retracted position;
an operation element supported on the main body in a protrudable-retractable manner, wherein the operation element is configured to move between a protruding position and a retracted position;
a locking mechanism configured to lock the pin in the protruding position; and
a lock releasing mechanism configured to unlock the pin in response to pressing of the operation element toward the retracted position, wherein
a tip of the pin is higher than a tip of the operation element, and
the operation element is substantially adjacent to the pin.

10. A positioning apparatus comprising:
a main body located near or in contact with a component;
a pin supported on the main body in a protrudable-retractable manner, wherein the pin is configured to move between a protruding position and a retracted position;
a plurality of operation elements supported on the main body in a protrudable-retractable manner, wherein the plurality of operation elements are each configured to move between a protruding position and a retracted position;
a locking mechanism configured to lock the pin in the protruding position; and
a lock releasing mechanism configured to unlock the pin in response to pressing of the plurality of operation elements toward the retracted position.
